(19) United States
(12) Patent Application Publication
(10) Pub. No.: US 2006/0112083 A1
(43) Pub. Date: May 25, 2006

(54) Object relation information management program, method, and apparatus

(75) Inventors: Masaaki Takase, Kawasaki (JP); Shinji Yamane, Yokohama (JP)

Correspondence Address: KATTEN MUCHIN ROSENMAN LLP, 575 MADISON AVENUE, NEW YORK, NY, 10022-2585, US

(73) Assignee: Fujitsu Limited

(21) Appl. No.: 11/075,446

(22) Filed: Mar. 8, 2005

(30) Foreign Application Priority Data
Nov. 19, 2004 (JP) 2004-336550

(51) Int. Cl. G01R 31/08

(52) U.S. Cl. 707/3

(57) ABSTRACT

A registration request for relation information between objects is received from a user terminal, and object relation information containing a type of relations between objects and a relation direction represented by a linking source and a linking destination is stored in a storage device in response to the registration request.

### BACKGROUND OF THE INVENTION

1. Field of the Invention

The present invention relates to a management system for data in business fields forming services, that is, relation information about objects, by a division of labor or a cooperation among different enterprisers using various function devices, etc., and more specifically to an object relation information management program, method, and apparatus for centrally managing object relation information containing a relation type and a relation direction between objects in various formats independent of services.

2. Description of the Related Art

Recently, a new network service business such as a ubiquitous service, etc. has been developed. In this service, by incorporating the functions and facilities at various stages in daily life into a part of services through network functions, evolved network services different from the existing mobile services which require carrying along all functions as terminals can be provided.

In the above-mentioned service, the data, that is, the information about an object unit, is required together with object relation information indicating the relation between, for example, two objects. By managing the object relation information and providing the information for each service enterpriser, various services different from the conventional services can be provided.

As a conventional technology, it is provided a technology in delivering contents, etc. using the object reference information. In the technology, all the data is centrally managed as an object, and relation information between objects is maintained and managed in a system.

However, in the above-mentioned technology, for example, object relation information for a specific purpose is managed as in network management. Therefore, it is necessary to provide a device for managing the relation information corresponding to each service. That is, it is necessary to maintain and manage the necessary information for each service in a duplicate manner, and the total amount of information is enormously large. Therefore, when various services are to be offered, it is necessary to reduce the total amount of information by maintaining and managing relation information independent of the services and freely processing the information by the services in reference to the relation information.

As described above, when various services are to be provided using object relation information, it is necessary to provide relation information for each service. However, in this case, there are the following problems. First, the information individually provided for a service can also be provided for another service. Second, when there are a number of pieces of information for the respective services in the extreme case, there is an enormous amount of information to be, managed.

Therefore, although it is necessary to manage object relation information by avoiding the duplicate assignment of the same information for services, there are also the following problems when the object relation information is centrally managed. First, in the conventional technology, since only the information that, for example, two objects are related as relation information, it is necessary to change the allocation of data depending on the service to be provided, thereby hardly enabling the appropriate central management of objects.

Second, when a service is to refer to the relation information about objects being managed, different reference results are to be output for the respective services. However, it is impossible to obtain flexible reference results because only the information about two related objects is managed as object relation information.

Third, when the object relation information changes, it is necessary to notify the service of the change during service providing process. However, in the conventional technology, it is difficult to specify the notification condition. When the condition cannot be specified, it is necessary to notify all services of the change of the relation information, and the notification is complicated when a number of services refer to the relation information.

Fourth, since object relation information is managed only by the information that two objects are related, the retrieval speed can be lowered when aggregated information is searched.

### SUMMARY OF THE INVENTION

The present invention has been developed to solve the above-mentioned problems and aims at providing an object relation information management system for offering object relation information in a generally used format, not in a specific service format. That is, by maintaining and managing object relation information in a format regardless of a service type by managing the object relation information in the format including the relation type and the relation direction represented by a linking source and a linking destination, the total amount of information can be reduced, the object relation information can be easily searched, and the change of the information can be easily notified.

The object relation information management apparatus according to the present invention comprises a communication management device and an object relation information management device to manage the relation between objects. The communication management device receives from a user terminal a registration request for the relation information between objects. In response to the registration request, the object relation information management device stores object relation information including the relation type of the objects and the relation direction represented by a linking source and a linking destination.

### BRIEF DESCRIPTION OF THE DRAWINGS

FIG. 1 is a block diagram showing the principle of the functions of the object relation information management program according to the present invention;

FIG. 2 shows the basic configuration of the object relation information management system according to an embodiment of the present invention;

FIG. 3 is a block diagram showing the detailed functional configuration of the object relation management apparatus;

FIG. 4 shows an example of object management data;

FIG. 5 shows an example of object relation management data;

FIG. 6 shows an example of object relation definition data;

FIG. 7 shows an example of relation change log data;

FIG. 8 shows an example of log cache data when a relation change notification condition is set;

FIG. 9 shows an example of log cache data when a relation change notification is made;

FIG. 10 shows an example of notification condition management data;

FIG. 11 shows an example of service control data;

FIG. 12 shows an example of the entire sequence of the object relation managing process;

FIG. 13 shows an example of an object relation information registration sequence;

FIG. 14 shows an object relation information registration request;

FIG. 15 shows an example of an object relation information registration reply;

FIG. 16 shows an example of an object relation information deletion sequence;

FIG. 17 shows an example of an object relation information deletion request;

FIG. 18 shows an example of an object relation information deletion reply;

FIG. 19 shows an example of an object relation information change sequence when a changing method is set;

FIG. 20 shows an example of an object relation information change sequence when a changing method is not set;

FIG. 21 shows an example of an object relation information change request;

FIG. 22 shows an example of an object relation information change reply;

FIG. 23 shows an example of an object relation information reference sequence;

FIG. 24 is a detailed flowchart of the object relation information retrieving process;

FIG. 25 shows an example of an object relation information reference request when a relation type is inquired about;

FIG. 26 shows an example of a reply in response to the reference request shown in FIG. 25;

FIG. 27 shows an example of an object relation information reference request when a linking destination object is inquired about;

FIG. 28 shows an example of a reply in response to the reference request shown in FIG. 27;

FIG. 29 shows an example of an object relation information reference request when all specified relation information relating to an object is inquired about;

FIG. 30 shows an example of a reply in response to the reference request shown in FIG. 29;

FIG. 31 shows an example of an object registration sequence;

FIG. 32 shows an example of an object registration request;

FIG. 33 shows an example of an object registration reply;

FIG. 34 shows an example of an object deletion sequence;

FIG. 35 shows an example of an object deletion request;

FIG. 36 shows an example of an object deletion reply;

FIG. 37 shows an example of a change notification condition setting sequence;

FIG. 38 shows an example of a change notification condition setting request;

FIG. 39 shows an example of a change notification condition setting reply;

FIG. 40 shows an example of a change notification condition deletion sequence;

FIG. 41 shows an example of a change notification condition deletion request;

FIG. 42 shows an example of a change notification condition deletion reply;

FIG. 43 shows an example of a relation information change notification sequence;

FIG. 44 is a detailed flowchart of the notification condition check process;

FIG. 45 shows an example of a relation information change notification; and

FIG. 46 is an explanatory view of loading a program according to the present invention into a computer.

### DETAILED DESCRIPTION OF THE PREFERRED EMBODIMENTS

The best mode for embodying the present invention is explained below by referring to the attached drawings.

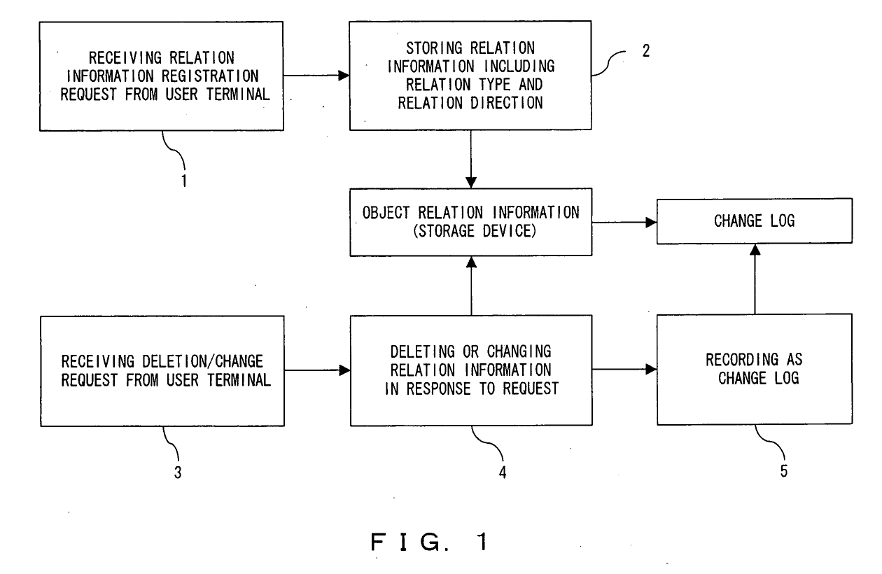

FIG. 1 shows the principle of the functions of the object relation information management program according to the present invention. FIG. 1 shows the principle of the configuration of the functions of the object relation information management program used by a computer for managing the relation between objects. In FIG. 1, a registration request for the relation information between objects from a user terminal is received in procedure 1 by a computer, and in response to the registration request, object relation information including a relation type and a relation direction represented by a linking source and a linking destination is stored in the storage device in procedure 2 by the computer.

The object relation information management program according to the present invention is used by a computer to receive a deletion/change request of the relation information between the objects from a user terminal in procedure 3, to delete/change the object relation information stored in the storage device in procedure 4 in response to the deletion/change request, and to record a registration/deletion/change result of the relation information as a change log in procedure 5.

According to another embodiment of the present invention, a computer can furthermore execute an object relation information management program of a notification execution procedure in which when a condition is externally set, and the condition is satisfied by the contents of the change log, the notification condition under which the contents of the change log are externally notified is managed, and when the object relation information satisfying the notification condition is registered, deleted, or changed, a notification is externally issued. In this case, when the notification condition is externally received, the computer can further execute the procedures of generating a log cache having an area storing the contents of the change log in response to the notification condition and reflecting the registration/deletion/change result of the object relation information on the contents of the log cache, and, in the notification execution procedure, the computer can judge whether or not the notification condition is satisfied by the contents of the log cache. Furthermore, in the notification execution procedure, depending on the contents of the log cache for a specified object, the notification condition is filtered based on the relation type and the number of relations, and a notification can be externally issued depending on the notification condition of the filtering result.

According to a further embodiment of the present invention, the object relation information management program can direct a computer to perform the procedures of externally receiving a retrieval request for the relation information about a specified object, filtering the relation information about the object specified in response to the retrieval request based on the relation type and relation direction, and externally outputting a filtering result as a retrieval result.

The object relation information managing method according to the present invention corresponds to the object relation information management program according to the present invention, receives from a user terminal a registration request for the relation information between objects, and stores in the storage device the object relation information including the relation type between objects and a relation direction represented by a linking source and a linking destination in response to the registration request.

According to an embodiment of the present invention, as with the above-mentioned program, object relation information is deleted or changed in response to the deletion/change request of an object from a user terminal, the result can be stored as a change log, an externally received notification condition can be managed, a notification can be externally issued when object relation information satisfying the notification condition is registered, deleted, or changed, and when the notification condition is externally received, the log cache can be generated, a registration/deletion/change result of object relation information can be reflected by the contents of the log cache, and it is judged whether or not the notification condition can be satisfied depending on the contents of the log cache when the notification is externally made.

The object relation information management apparatus according to the present invention comprises a communication management device for receiving from a user terminal a registration request for relation information between objects, and an object relation information management device for storing object relation information including a relation type between objects and a relation direction represented by a linking source and a linking destination in response to the registration request.

In an embodiment of the present invention, the communication management device of the object relation information management apparatus receives a deletion/change request for relation information, the object relation information management device deletes or changes the object relation information, and a change log management device for storing a registration/deletion/change result of relation information as a change log can be further provided.

In another embodiment, a notification condition management device for managing a notification condition and externally issuing a notification when object relation information satisfying the notification condition is registered, deleted, or changed can also be provided, or, when the notification condition is externally received, the change log management device can generate a log cache having an area storing the contents of the change log based on the notification condition, reflect the registration/deletion/change result of the object relation information by the contents of the log cache, and the notification condition management device can determines whether or not the notification condition can be satisfied based on the contents of the log cache.

The object relation information can be managed by the relation type and the relation direction in a general-purpose format without a limit to a specific service. Furthermore, the relation type can be easily added, thereby further expanding the general versatility.

The condition for a change notification of relation information can be set by a relation type and the number of relations corresponding to a key object, and a process can be simplified by issuing a change notification about relation information only when a specified condition is satisfied. Additionally, a log cache is generated corresponding to a condition based on the specification of a change notification condition, and a necessary retrieval speed for a change notification can be prevented from being lowered by using the log cache.

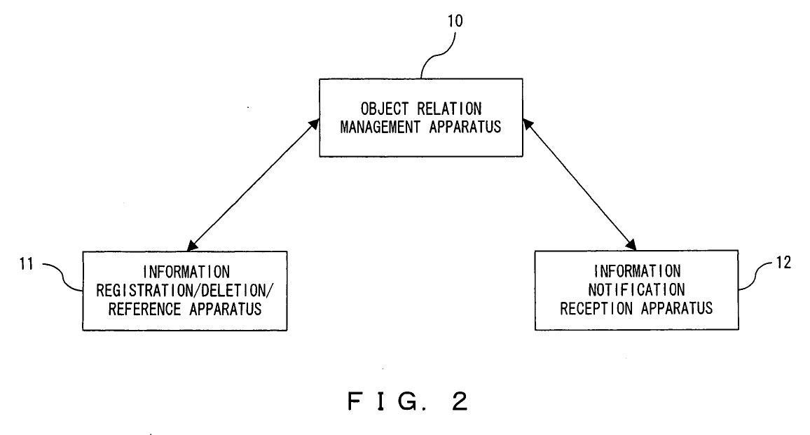

FIG. 2 is a block diagram of the entire configuration of the relation information management system using the object relation information management system according to the present invention. In FIG. 2, the system comprises an object relation management apparatus 10, an information registration/deletion/reference apparatus 11, and an information notification reception apparatus 12.

The object relation management apparatus 10 maintains and manages a relation type and a relation direction as relation information between objects. A relation type of an object can be defined as, for example, “owning” a device by a user when one of two objects indicates a user while the other object indicates a device. As a relation direction, the relation of direction between a linking source and a linking destination is defined to indicate that, in this case, the user is a linking source object, and there is a device as a linking destination object.

The object relation management apparatus 10 registers and deletes an externally received object, and performs a specified process in response to a registration, deletion, reference, and change request message for relation information. When there is a change corresponding to a relation information notification condition in response to a externally received notification condition setting request messages a notification is issued about a change of the relation information to a specified device.

The information registration/deletion/reference apparatus 11 transmits to the object relation management apparatus 10 a registration for an object itself and a registration, deletion, change, or reference request for object relation information, and receives a result in response to the reference request.

The information notification reception apparatus 12 transmits the notification condition setting request to the object relation management apparatus 10, and receives a relation information change notification when there is a change of the relation information matching the notification condition.

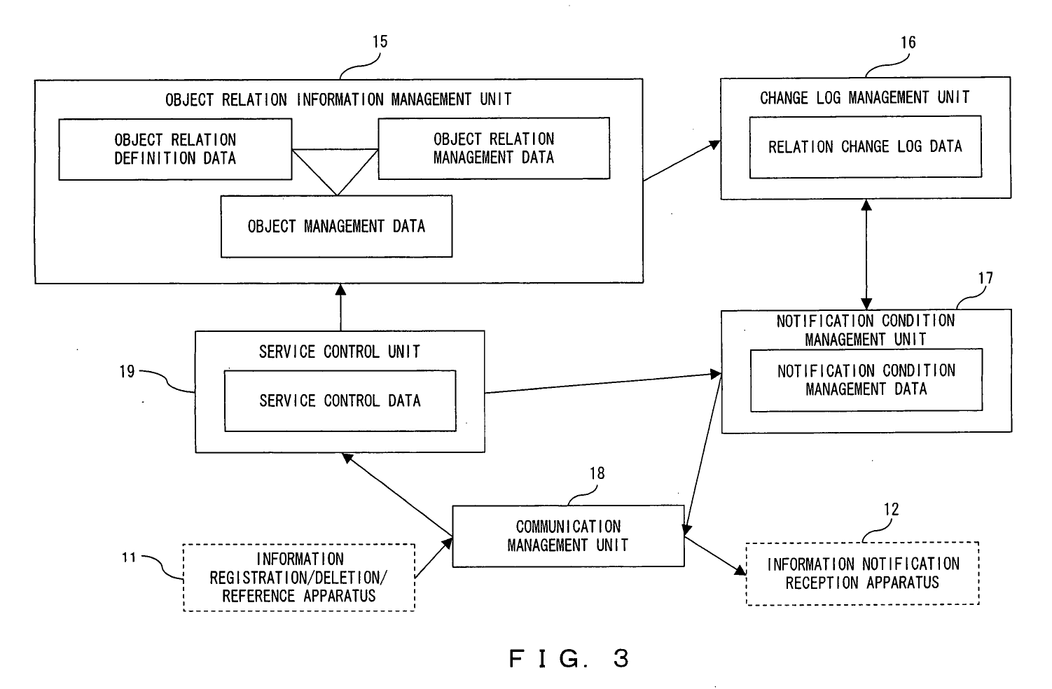

FIG. 3 is a detailed block diagram of the configuration of the object relation management apparatus 10. In FIG. 3, the object relation management apparatus 10 comprises an object relation information management unit 15 for managing the information about an object itself and object relation information, a change log management unit 16 for recording a change as a log when a change of relation information, etc. occurs, a notification condition management unit 17 for managing a notification condition for externally issuing a notification about a change result of the relation information managed by the change log management unit 16, a communication management unit 18 for communicating data with an external unit, for example, transmitting and receiving a packet, and a service control unit 19 for receiving an external request, etc. and assigning the request to the object relation information management unit 15, etc. As shown in FIG. 2, the communication management unit 18 is connected to the information registration/deletion/reference apparatus 11 and the information notification reception apparatus 12.

The object relation information management unit 15 manages three types of data, that is, object management data, object relation definition data, and object relation management data. The object management data is the information about an object itself, and the minimal information is an identifier indicating an object. The object relation management data is used in managing the relation information, that is, as described above, the relation type and the relation direction as the relation information between two objects basically. The object relation definition data is used in managing the definition of a relation type as the most fundamental information in the object relation information. The relation type is variable data, that is, any additional data can be accepted. Thus, by enabling to add a relation type, object relation information corresponding to various services can be processed, thereby performing general management regardless of services.

When object relation information is registered, deleted, or changed, the change log management unit 16 manages the information as relation change log data, and it manages the log about the key object corresponding to the notification condition as a cache in response to the request from the notification condition management unit 17. Correspondingly, the notification condition management unit 17 requests the change log management unit 16 to store the log cache about the key object specified in the notification condition.

The service control unit 19 instructs each unit to perform a process in response to a registration, reference, deletion, or change request for relation information, and has a corresponding request as service control data and its format data.

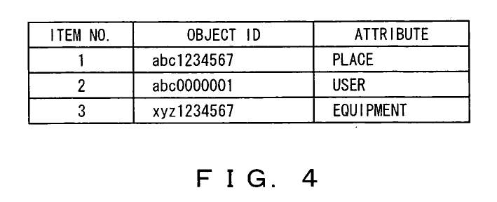

FIGS. 4 through 6 show examples of data managed by the object relation information management unit 15. FIG. 4 shows an example of object management data, and, as described above, the object ID as an identifier of an object in the management data is the minimal information, and can manage the attribute (type, etc.) of an object.

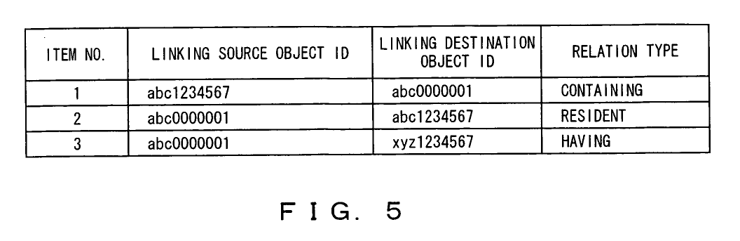

FIG. 5 shows an example of object relation management data. In FIG. 5, the relation direction between two objects is indicated by a linking source object ID and a linking destination object ID, and the corresponding relation type is indicated. For example, the linking source object of the data of item No. 1 has a place as an attribute as shown in FIG. 4, and the linking destination object has a user as an attribute. As a relation type, a place accommodating a user is indicated.

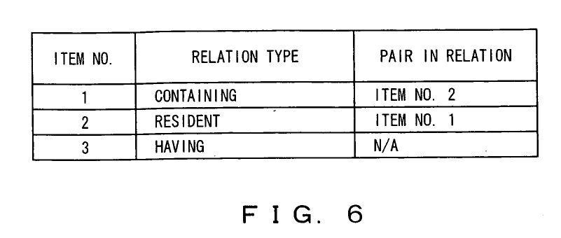

FIG. 6 shows an example of object relation definition data. In the data, at least a relation type is required, and object relation definition data can be described only corresponding to the relation type contained in the data. In the data, the relation type of accommodating the data of item No. 1 indicates that the type is a pair to the relation type No. 2 indicating “resident”.

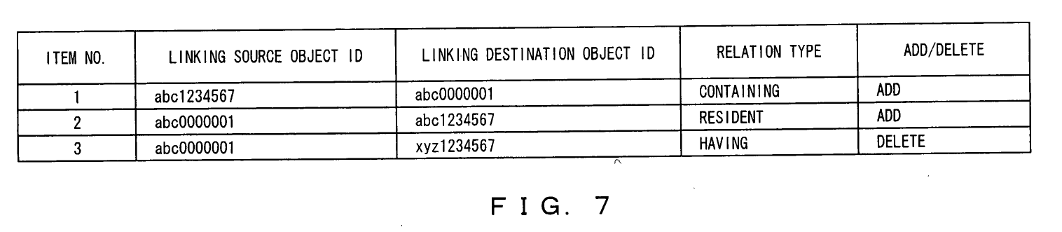

FIG. 7 shows an example of relation change log data managed by the change log management unit 16. The relation change log data holds all changed contents as log data when object relation information is changed by registration (addition), deletion, etc. For example, relating to the data of item No. 3, it is recorded as log data that the object relation information about an object having the user attribute as a linking source object has an object having the attribute of equipment as a linking destination object has been deleted.

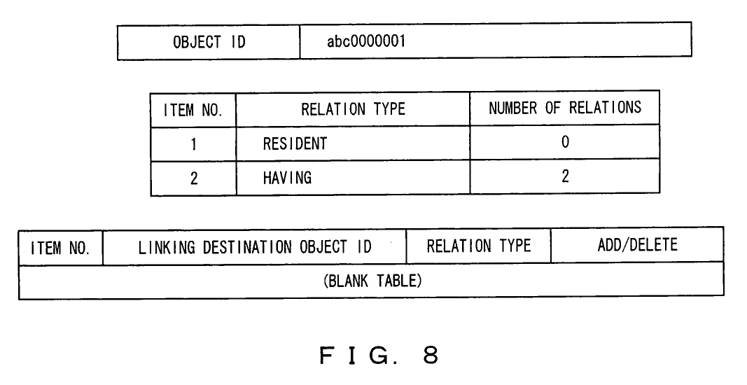

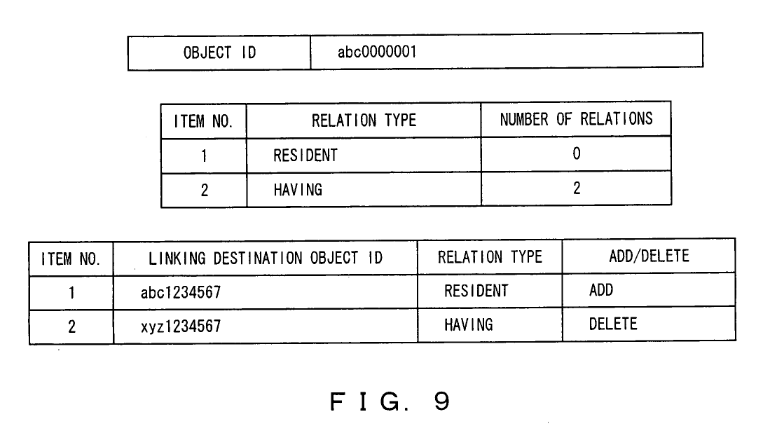

FIGS. 8 and 9 are explanatory views of examples of log cache in which when a notification condition is set as notification condition management data managed by the notification condition management unit 17, the relation information about a key object is set corresponding to a notification condition, and the contents are changed when the relation information is changed. FIG. 8 shows a log cache of the relation information for the object having an ID of abc0000001 which is a key in a certain status. In this example, the number of relations whose relation type is “having”, that is, there is two links, is indicated as the relation information about the object.

FIG. 9 shows the log cache about the linking source object abc0000001 when the relation between abc0000001 and abc1234567 is added and the relation between abc0000001 and xyz1234567 is deleted after the status shown in FIG. 8, and indicates that the number of relations having the type “resident” is added by 1 and the number of relations having the type “having” is reduced by 1.

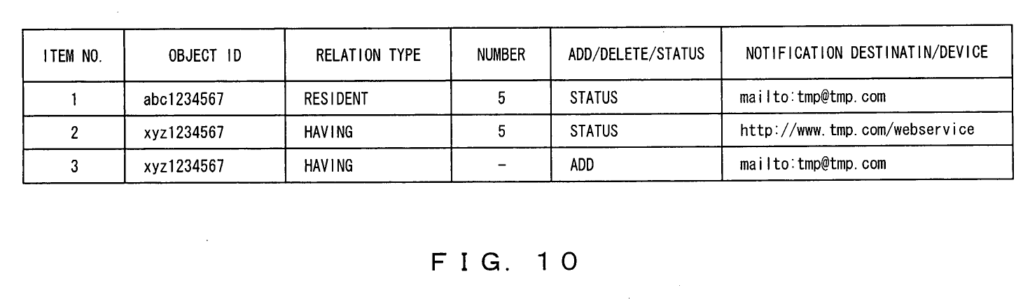

FIG. 10 shows an example of notification condition management data managed by the notification condition management unit 17. FIG. 10 shows that when the number of relations having the type “resident” as a relation type becomes 5 between the object having the ID of abc1234567 as the data of item No. 1 and another object, that is, when the number of relations becomes 5 by adding or deleting relation information, mail is to be transmitted to a specified address. In the data having item No. 3, it is indicated that when the relation information having a type “having” between the objects of xyz1234567 is added, mail is to be transmitted.

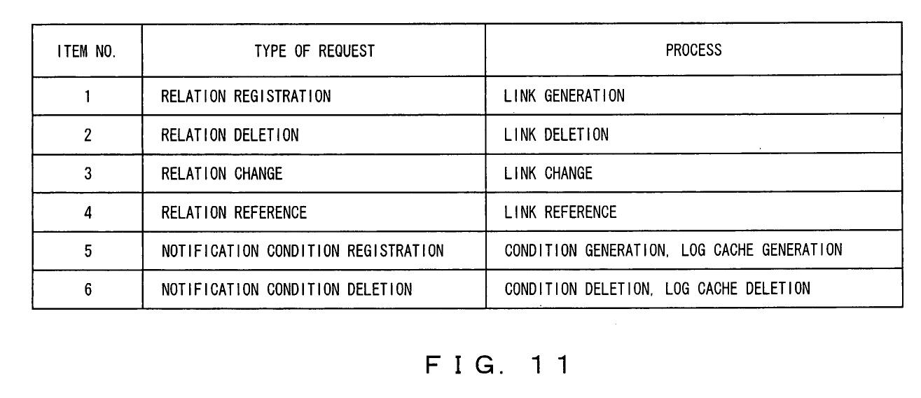

FIG. 11 shows an example of service control data to be managed by the service control unit 19. In FIG. 11, the requests from the relation registration of item No. 1 to the relation reference of item No. 4 relate to the relation information itself, and these requests are transmitted from the service control unit 19 to the object relation information management unit 15, and a corresponding process is performed on them. The requests of the notification condition registration of item No. 5 and the notification condition deletion of item No. 6 are transmitted to the notification condition management unit 17 for addition and deletion of notification condition management data, and the change log management unit 16 correspondingly generates and deletes a log cache.

Thus, the data for the object relation management apparatus shown in FIG. 3 is described above, and the embodiments of the present invention are described below further in detail including the sequence of each process performed on the apparatus.

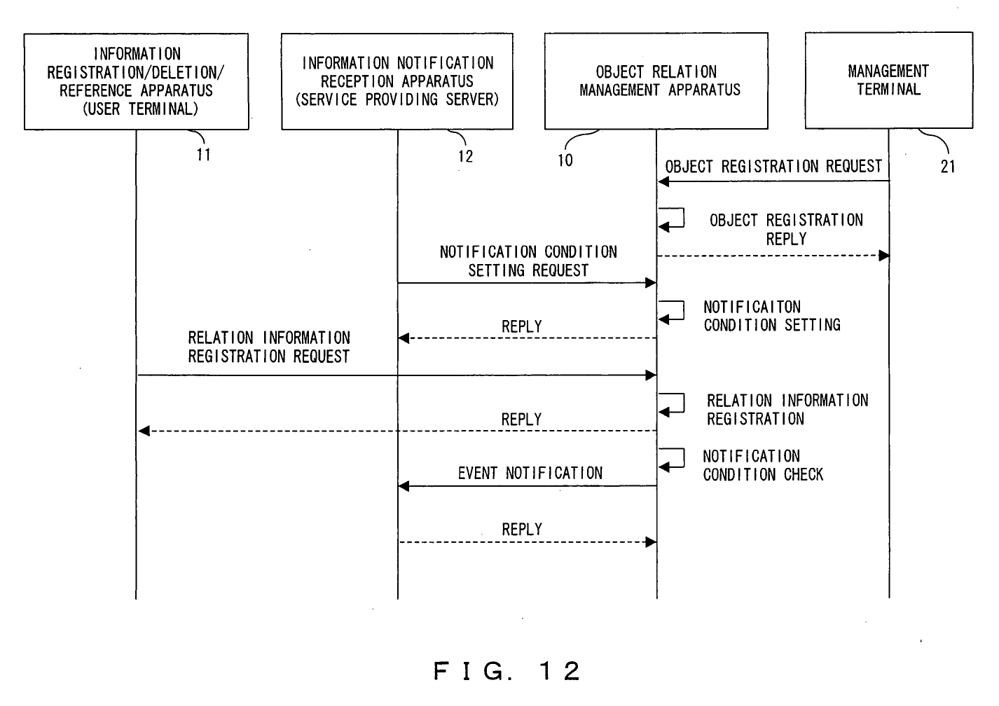

FIG. 12 is an explanatory view of the entire sequence of the process performed by the object relation management apparatus. In FIG. 12, first a management terminal, for example, a management terminal 21 which is a terminal for exclusively registering an object issues a registration request to the object relation management apparatus 10, the object is registered, and an object registration reply is returned to the management terminal 21. In this example, it is assumed that there is the management terminal 21 dedicated for registration of an object, but as described above, a user terminal corresponding to the information registration/deletion/reference apparatus 11 obviously can issue an object registration request to the object relation management apparatus 10.

A service providing server corresponding to the information notification reception apparatus 12 shown in FIG. 3 issues a notification condition setting request to the object relation management apparatus 10 when object relation information is changed. The object relation management apparatus 10 sets a notification condition, a log cache is generated corresponding to the notification condition, and a setting reply is returned to a service providing server 12. When the user terminal 11 issues a relation information registration request to the object relation management apparatus 10, the relation information is registered, a change in relation information is recorded as a log, and it is reflected by a log cache as necessary. Then a reply is returned to the user terminal 11, a notification condition as to whether or not a notification is to be issued in response to a change in relation information is checked, a change in relation information is reported as an event notification to the service providing server 12 when the notification condition is satisfied, and the service providing server 12 returns a reply that the event notification has been received to the object relation management apparatus 10. Upon receipt of the change notification, the service providing server 12 performs a predetermined service corresponding to the received information.

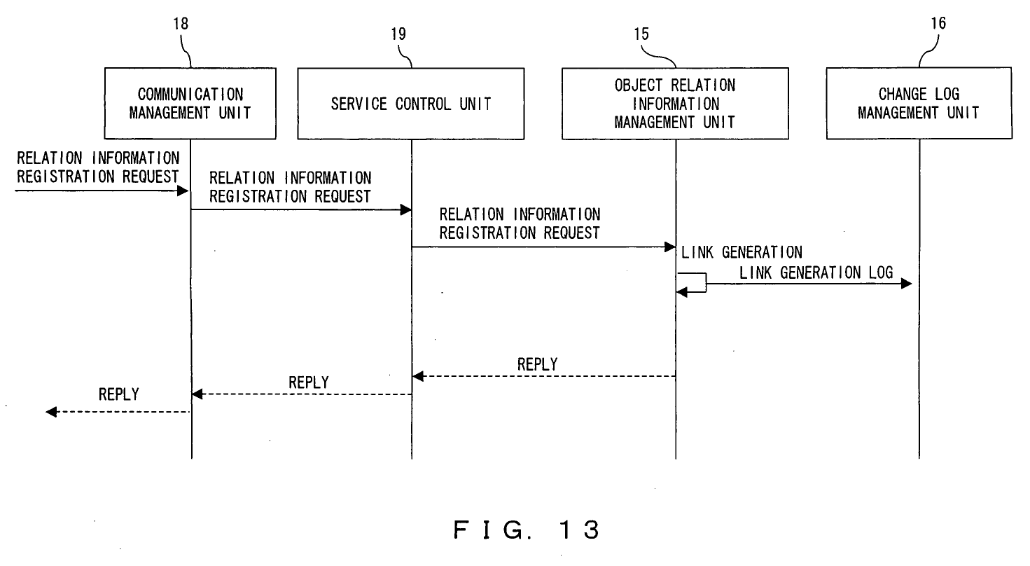

Described below is the detailed sequence of various processes contained in the entire sequence shown in FIG. 12. FIG. 13 is an explanatory view of an object relation information registration sequence. In FIG. 13, a relation information registration request transmitted from an external unit, for example, the information registration/deletion/reference apparatus 11 to the communication management unit 18 is basically transmitted as is to the object relation information management unit 15 through the service control unit 19. Then, a link corresponding to the relation information is generated, a link generation log is transmitted to the change log management unit 16, addition is made to the relation change log data explained above by referring to FIG. 7, the contents of the log cache is changed as necessary, and the object relation information management unit 15 externally returns a reply through the service control unit 19 and communication management unit 18.

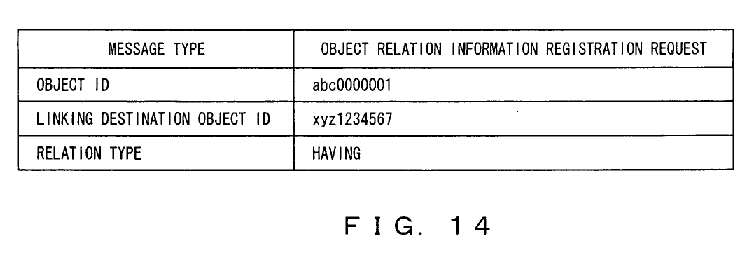

FIG. 14 shows an example of an object relation information registration request. An object relation information registration request as a message type, that is, an object ID as a linking source, a linking source object, and a relation type, are contained in the request.

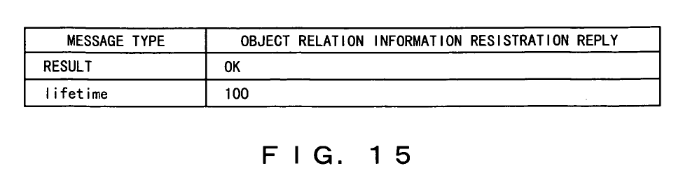

FIG. 15 shows an example of an object relation information registration reply corresponding to the registration request shown in FIG. 14, and shows that the registration has been correctly performed as a result.

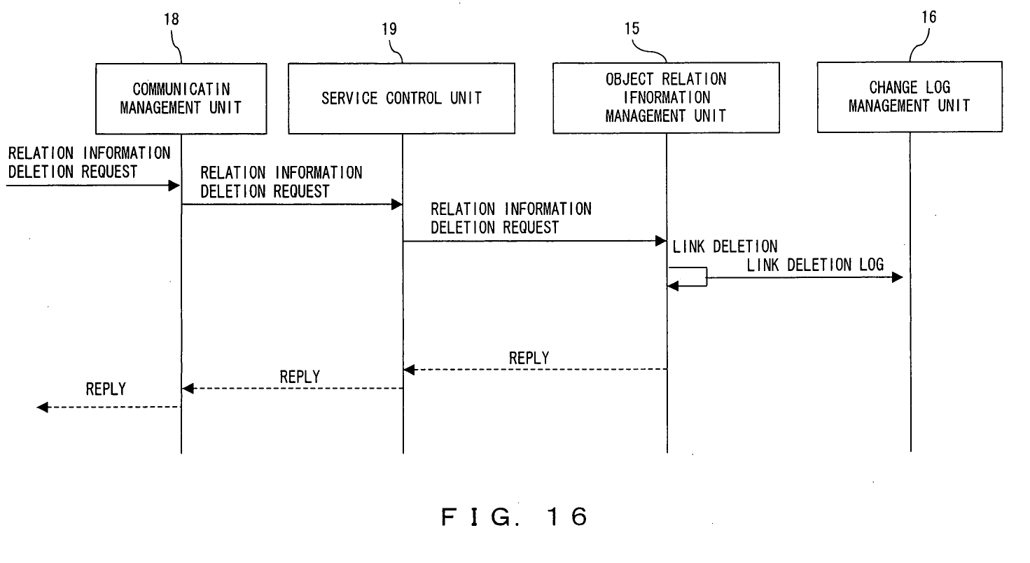

FIG. 16 shows an example of an object relation information deletion sequence. As in the sequence shown in FIG. 13, an external relation information deletion request is transmitted to the object relation information management unit 15 through the communication management unit 18 and the service control unit 19, a link is deleted, a link deletion log is transmitted to the change log management unit 16, the relation management data is deleted, and the contents of the log cache data are changed as necessary. In response to the relation information deletion request, a reply is externally returned.

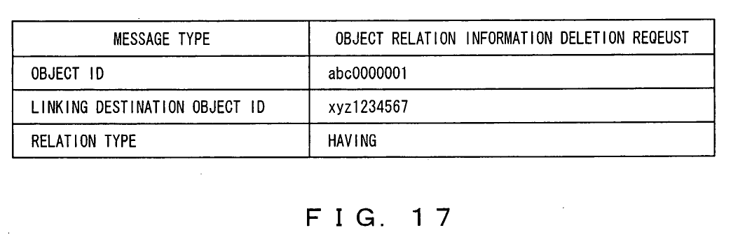

FIG. 17 shows an example of an object relation information deletion request. The message type, in this example, a linking source object ID, a linking destination object ID, and a relation type are contained in the request, in the same way with FIG. 14.

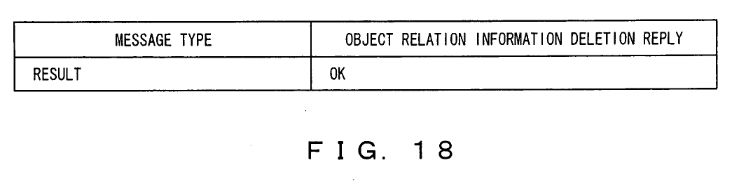

FIG. 18 shows an example of an object relation information deletion reply corresponding to FIG. 17. It shows that the deletion has been correctly performed.

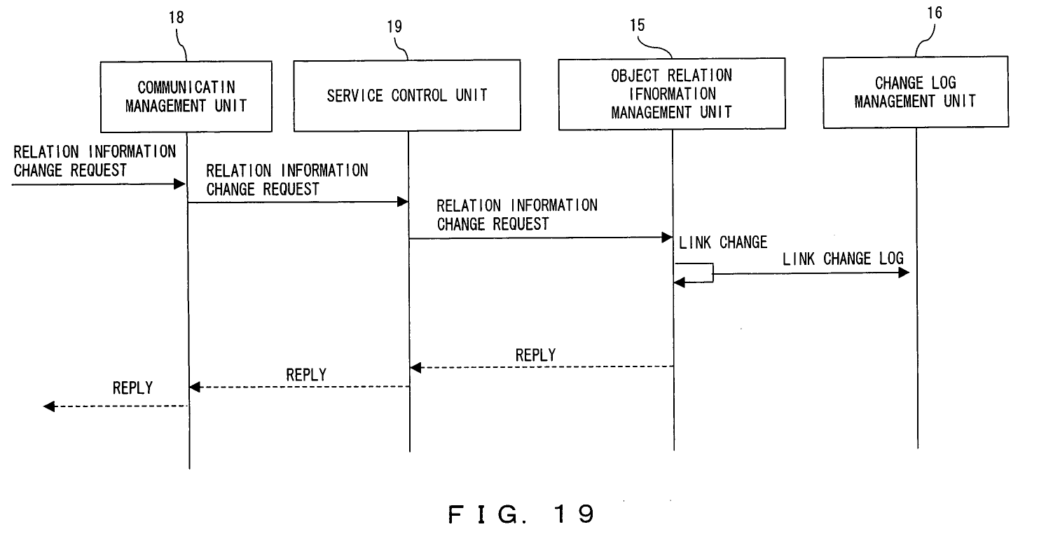

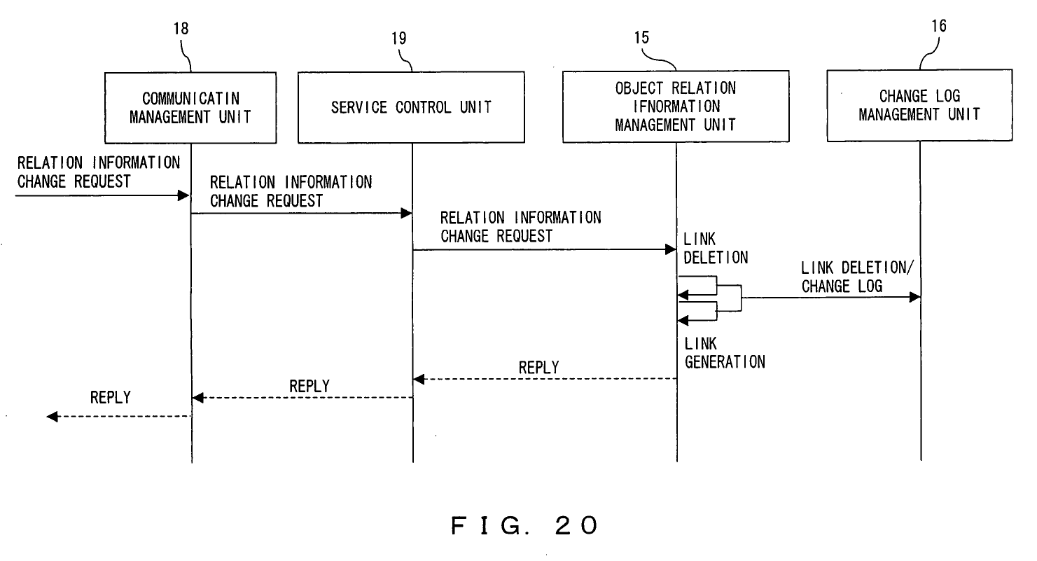

FIGS. 19 and 20 show examples of object relation information change sequences. In this object relation information changing process, basically a link corresponding to the relation information before a change is deleted, and a new link corresponding to the relation information after the change is generated. FIG. 19 shows the case in which a method including these two processes is given as a changing method, and FIG. 20 shows the case in which it is not given.

In FIG. 19, an external relation information change request is transmitted to the object relation information management unit 15 as the sequence shown in FIG. 13, etc., a link is changed in the changing method, a reply to the change is externally returned, a link change log is transmitted to the change log management unit 16, relation change log data is added, and the contents of the log cache are changed as necessary. In FIG. 20, the object relation information management unit 15 deletes and generates a link instead of changing a link in a changing method, and a link deletion/generation log is transmitted to the change log management unit 16.

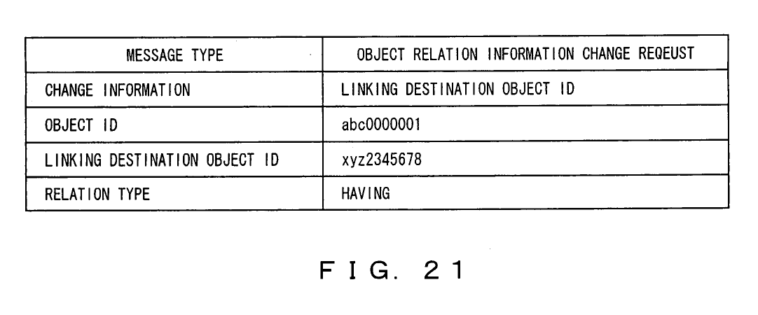

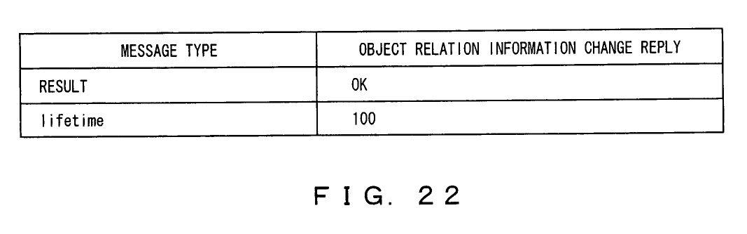

FIG. 21 shows an example of an object relation information change request. A message type is a registration request, the information to be changed is a linking destination object ID, the linking destination of an object having an ID of abc0000001 and linking destination object ID whose relation type is “having” is requested to be changed to xyz2345678. In this example, the linking destination object is only-one, but linking destination object IDs before and after a change are required when there are two or more linking destination objects. FIG. 22 shows an example of a reply in response to the change request shown in FIG. 21, and shows that a change has been appropriately made.

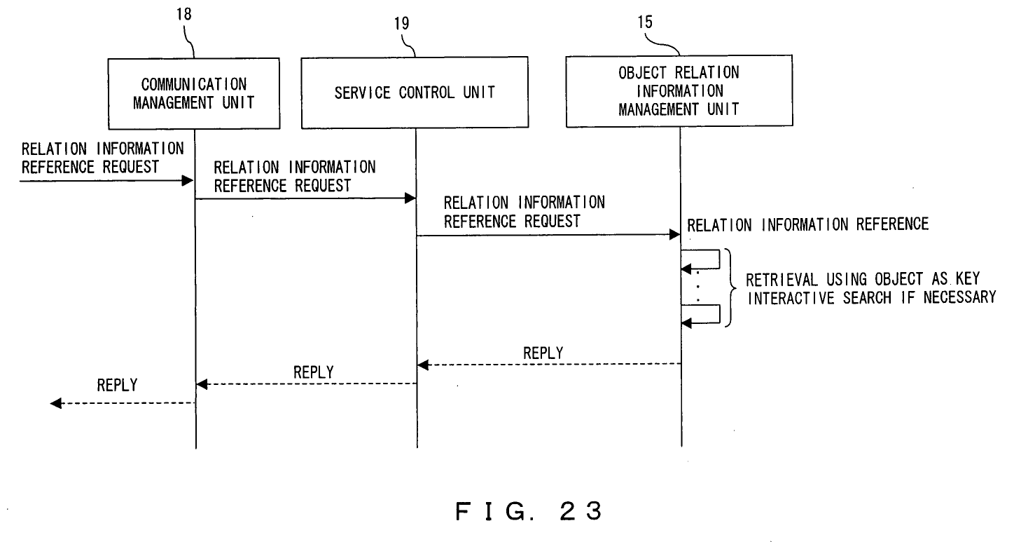

FIG. 23 shows an example of an object relation information reference sequence. In FIG. 23, an external relation information reference request is transmitted to the object relation information management unit 15 and the reference to the relation information is made using an object as a key, iterative retrieval is performed as necessary, and a reference result is externally returned as a reply.

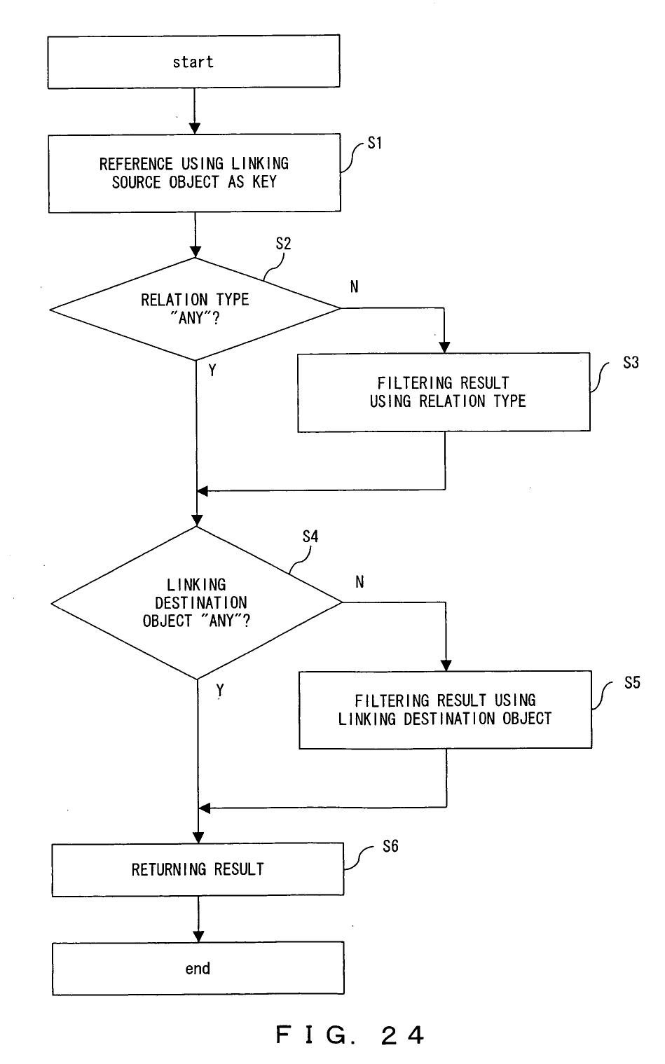

FIG. 24 is a detailed flowchart of the relation information reference process by the object relation information management unit 15 shown in FIG. 23. When the process is started as shown in FIG. 24, for example, the object relation management data explained above by referring to FIG. 5 is referred to using, for example, a specified linking source object as a key, and it is determined whether the relation type specified in step S2 is an arbitrary type or a specified type. If the relation type in the object relation information to be referred to is specified, then a reference result in step S1 is filtered by the relation type in step S3 and then control is passed to step S4. If it is an arbitrary type, control is immediately passed to step S4. In step S4, it is determined whether the linking destination object can be an arbitrary object or a specified object. If it is specified, the reference result is filtered by the linking destination object ID, etc. in step S5, and then a result is returned to, for example, the information registration/deletion/reference apparatus 11 in step S6, and the process terminates. If it can be an arbitrary object, a result is immediately returned to, for example, the information registration/deletion/reference apparatus 11, and the process terminates.

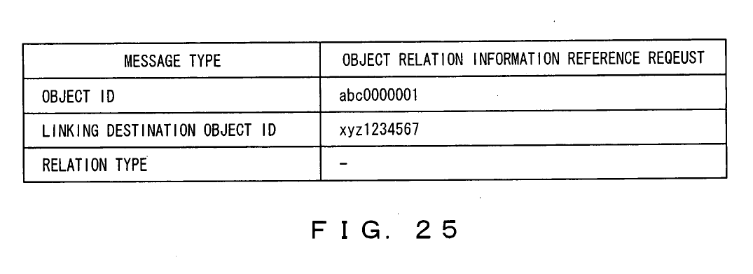

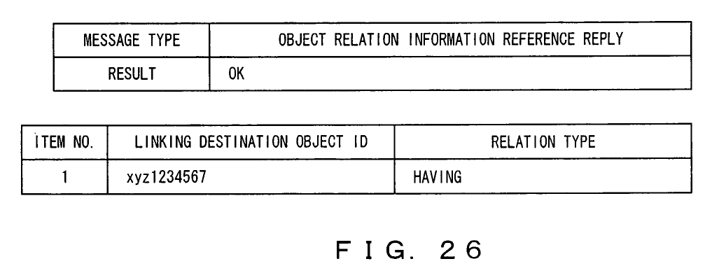

FIGS. 25 through 30 are explanatory views showing examples of object relation information reference requests and the replies in response to the requests. FIG. 25 shows an example of inquiring about a relation type as a relation information reference request. A reference request is transmitted with a blank column for relation type. FIG. 26 shows an example of a reply to the request. An appropriate reply is transmitted as a result, and the relation type “having” is returned.

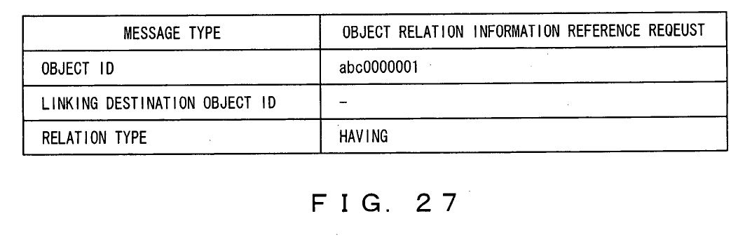

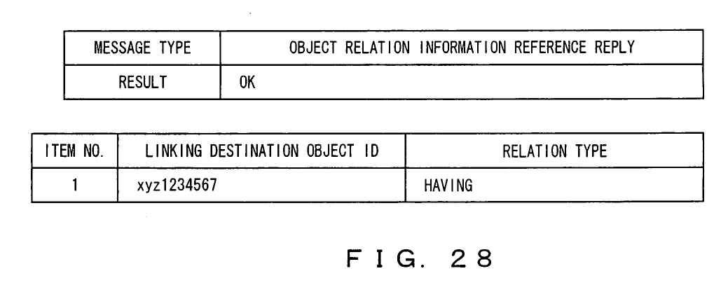

FIG. 27 shows an example of inquiring about a linking destination object of a specified object, and request is transmitted with a blank column for linking destination object ID. FIG. 28 shows an example of a reply to the request. An appropriate reply is returned as a result, and the linking destination object ID of xyz1234567 is indicated.

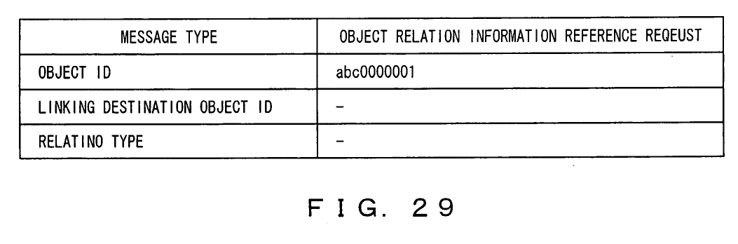

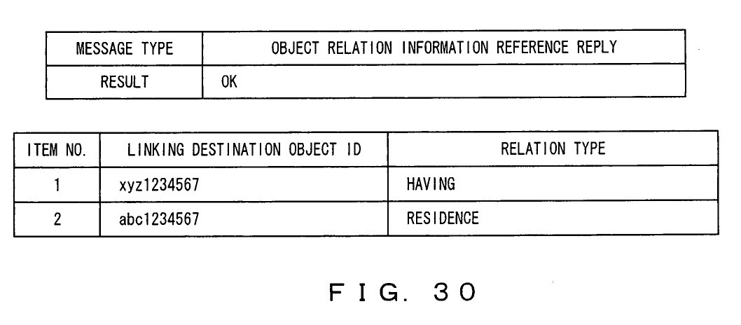

FIG. 29 shows an example of a reference request when all relation information about the specified object is inquired about, and shows all linking destination object IDs of the objects having the specified IDs and the relation types corresponding to them are inquired about. FIG. 30 shows an example of a reply to the request, shows an appropriate reply is returned, and two linking destination object IDs and the corresponding relation types are returned.

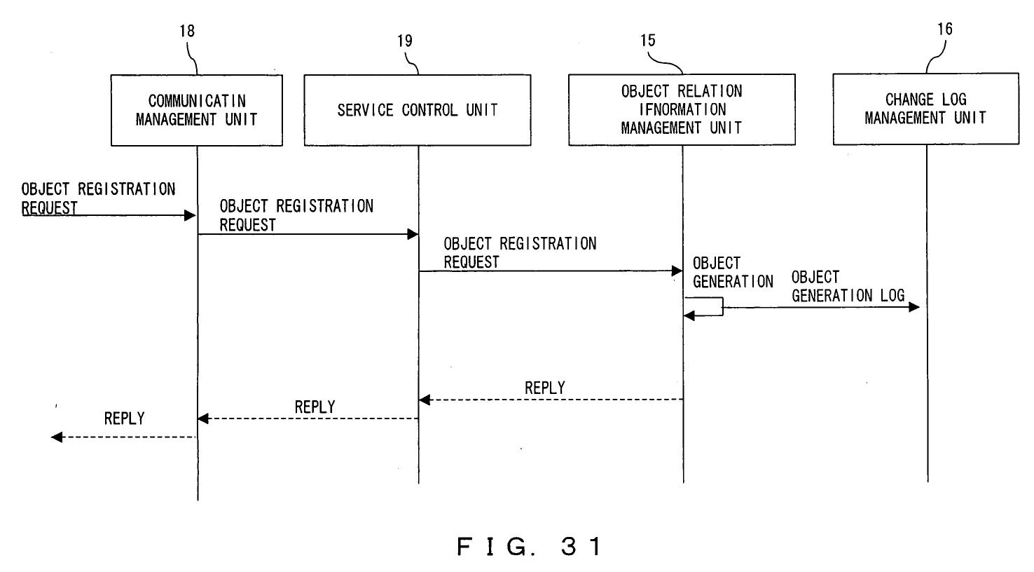

FIG. 31 shows an example of an object registration sequence. In FIG. 31, an external object registration request is basically transmitted as is to the object relation information management unit 15, an object is generated, a registration reply is externally returned, and an object generation log is transmitted to the change log management unit 16.

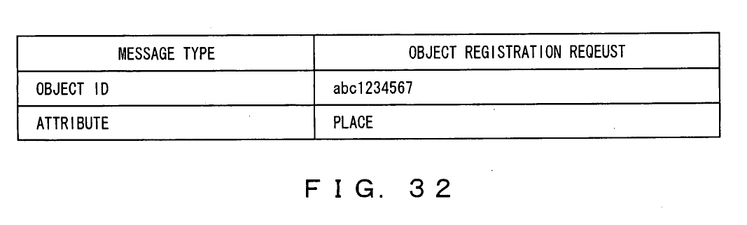

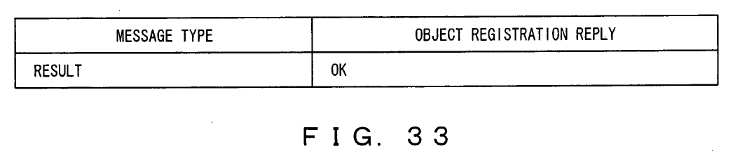

FIG. 32 shows an example of an object registration request, and indicates, corresponding to the message type of the object registration request, the ID of a registered object and its attribute. FIG. 33 shows an example of a reply to the request, and indicates that registration has been appropriately performed.

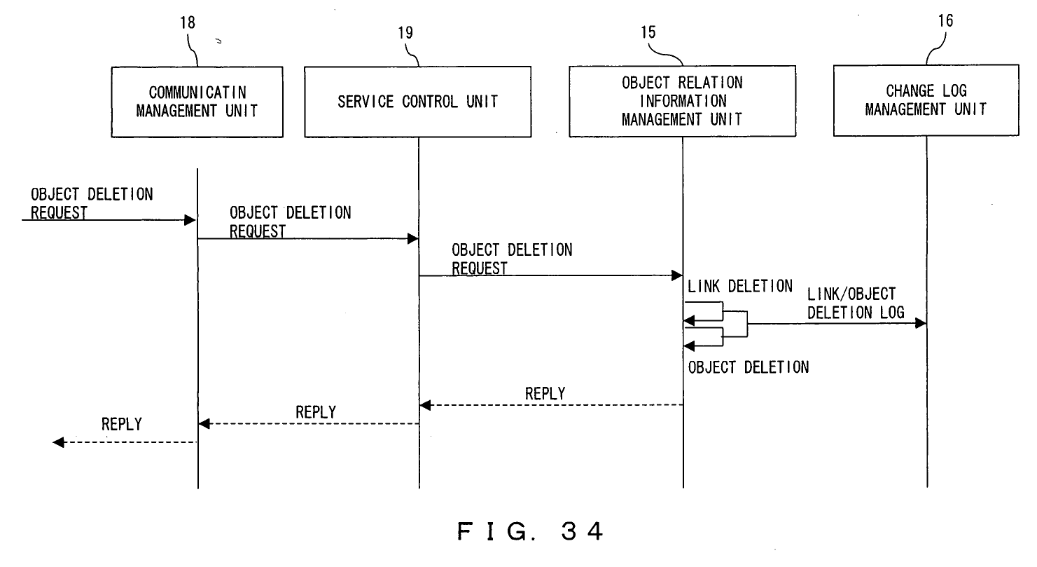

FIG. 34 shows an example of an object deletion sequence. In FIG. 34, an external object deletion request is transmitted as is to the object relation information management unit 15, all links about the object are deleted and the object itself is deleted, a deletion reply is externally returned, a link/object deletion log is transmitted to the change log management unit 16, the relation change log data explained above by referring to FIG. 7 is accumulated, and the contents of the log cache are changed as necessary.

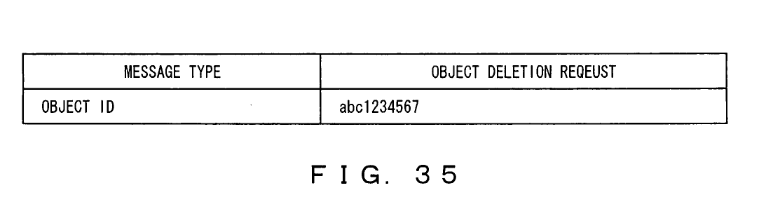

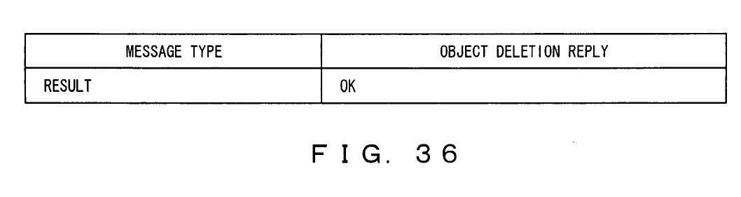

FIG. 35 shows an example of an object deletion request, and indicates the message type and the ID of the object to be deleted. FIG. 36 shows an example of a reply to the request, and indicates that deletion has been appropriately performed.

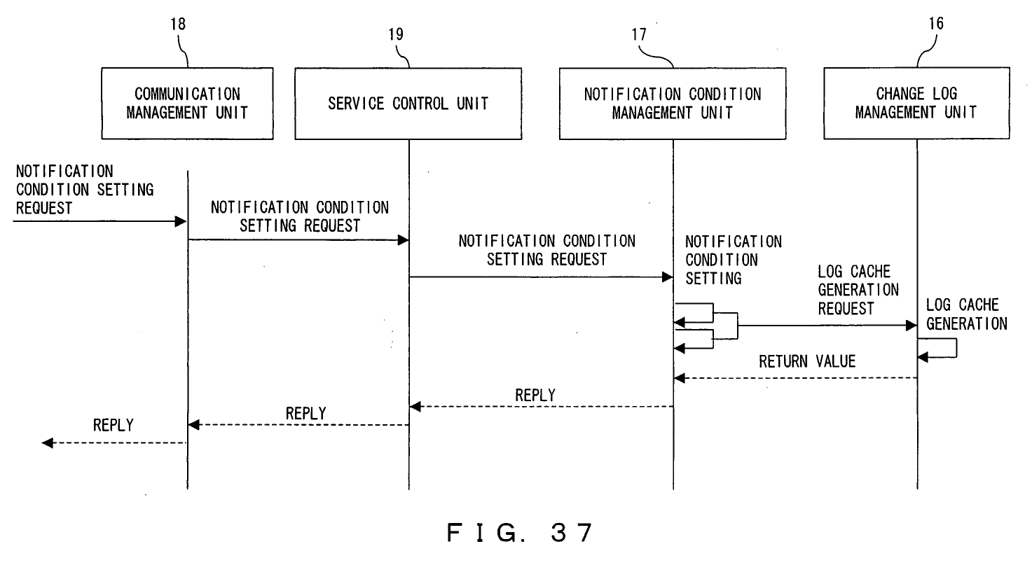

FIG. 37 shows an example of a change notification condition setting sequence. In FIG. 37, for example, a notification condition setting request transmitted from the information notification reception apparatus 12 is transmitted as is to the notification condition management unit 17, and the notification condition is set as notification condition management data, a setting completion reply is returned to the information notification reception apparatus 12, a log cache generation request is transmitted to the change log management unit 16, a log cache is generated, that is, a log area is reserved in a cache with the storable data stored in the cache, and log cache generation completion is returned as a return value to the notification condition management unit 17. It is possible to generate a plurality of log caches corresponding to the same object specified in each of a plurality of notification conditions, and it is also possible to add to a log cache a difference of relation types, etc. for a new notification condition when there is already the log cache corresponding to another notification condition.

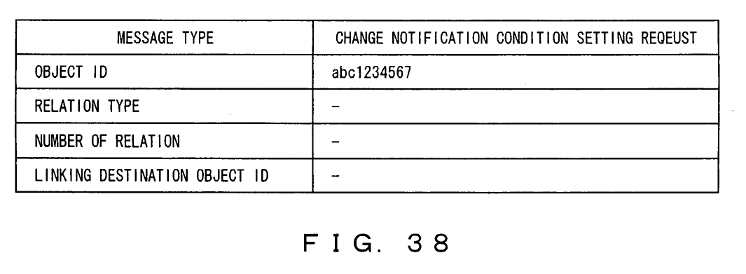

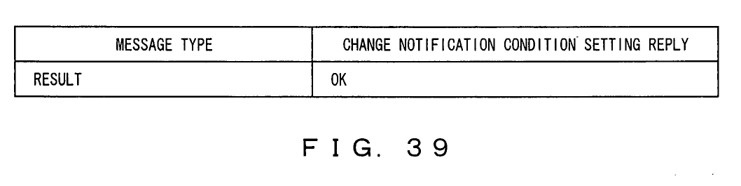

FIG. 38 shows an example of a change notification condition setting request, and indicates that a notification is to be issued when a change occurs in any of the relation type, the number of relations, and a linking destination object, corresponding to the object having the ID specified in FIG. 38. FIG. 39 shows an example of a reply to the request, and indicates that a change notification condition has been appropriately set.

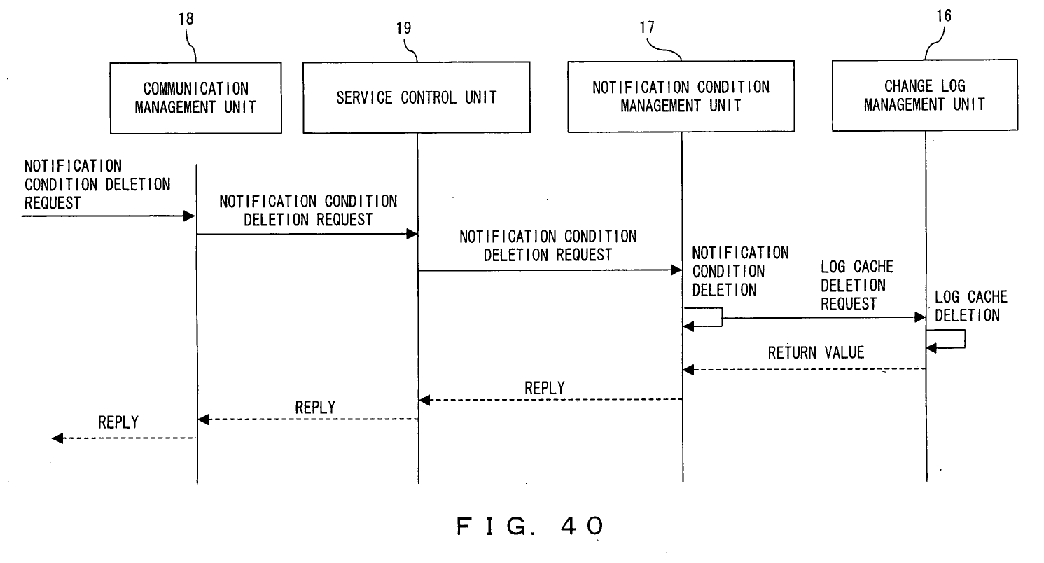

FIG. 40 shows an example of a change notification condition deletion sequence. For example, a notification condition deletion request from the information notification reception apparatus 12 is transmitted to the notification condition management unit 17, a notification condition in the notification condition management data is deleted, a reply message is returned to the information notification reception apparatus 12, a deletion request for a log cache is transmitted to the change log management unit 16, a corresponding log cache itself is deleted, and a return value is returned to the notification condition management unit 17. As described above, when only one log cache is generated for a plurality of notification conditions, only related types to the notification condition to be deleted.

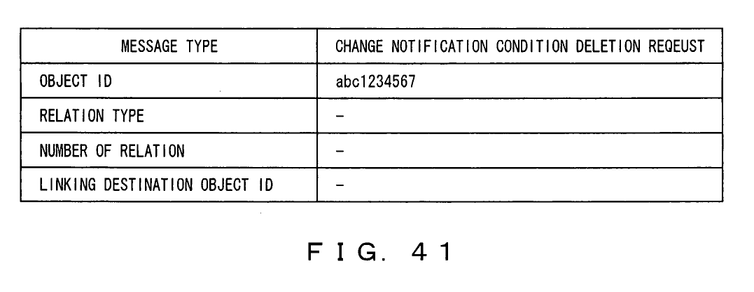

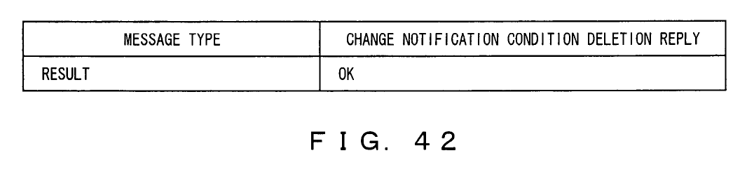

FIG. 41 shows an example of a change notification condition deletion request. The deletion of the change notification condition set for the change notification condition setting request explained by referring to FIG. 38 is requested. FIG. 42 shows an example of a reply to the request, and indicates that the deletion of the notification condition has been appropriately performed.

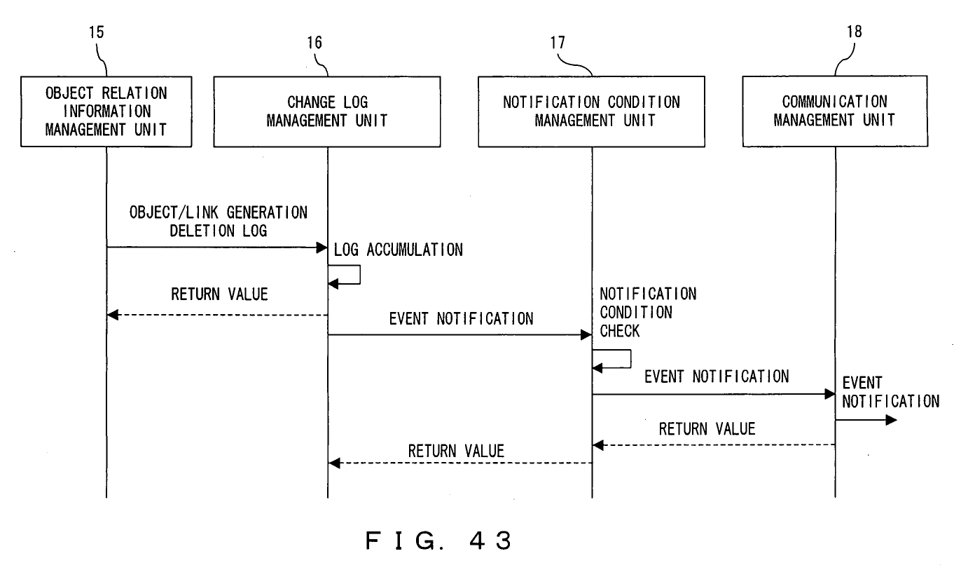

FIG. 43 shows an example of a relation information change notification sequence. When object/link generation and deletion logs are transmitted from the object relation information management unit 15 to the change log management unit 16, log data is accumulated, and a log cache is generated as necessary. Then, a return value is returned to the object relation information management unit 15, and the event notification is transmitted to the notification condition management unit 17.

The notification condition management unit 17 checks a notification condition. When the notification condition is satisfied, a relation information change is transmitted as an event notification to the information notification reception apparatus 12 through the communication management unit 18, and a return value in the system is transferred.

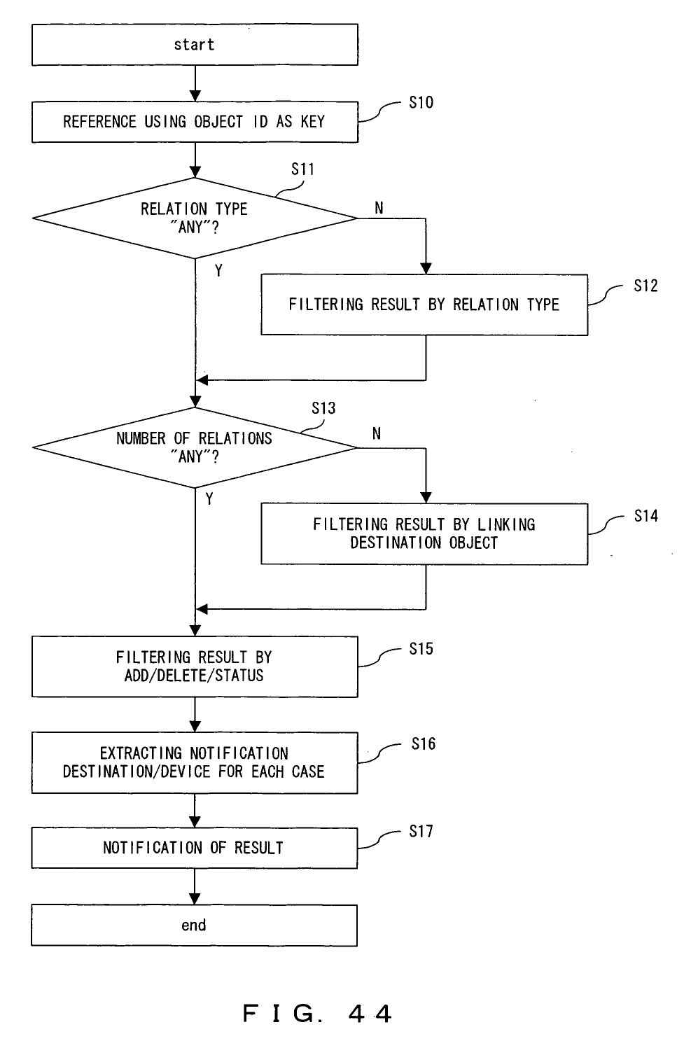

FIG. 44 is a detailed flowchart of the notification condition check process shown in FIG. 43. When the process is started as shown in FIG. 44, the notification condition management data and a log cache are referred to using as a key the ID of an object L corresponding to a change event in step S10, it is determined in step S11 whether or not the relation type specified by the notification condition for the data obtained as a reference result is an arbitrary type. If the relation type is specified, the reference result is filtered by the relation type in step S12, and then control is passed to step S13. If it can be an arbitrary type, control is immediately passed to step S13.

In step S13, it is determined whether or not the number of relations specified by the notification condition is an arbitrary number. If it is not an arbitrary number, then the filtering operation is performed using the number of linking destination objects in step S14, and then control is passed to step S15. If it can be an arbitrary number, control is immediately passed to step S15.

In step S15, the result up to step S14 is filtered using the contents of the add/delete/status columns shown in FIG. 10, a notification destination or a notification device is extracted corresponding to each notification condition of the filtering result in step S16, and the result is transmitted to the notification destination in step S17, thereby terminating the process.

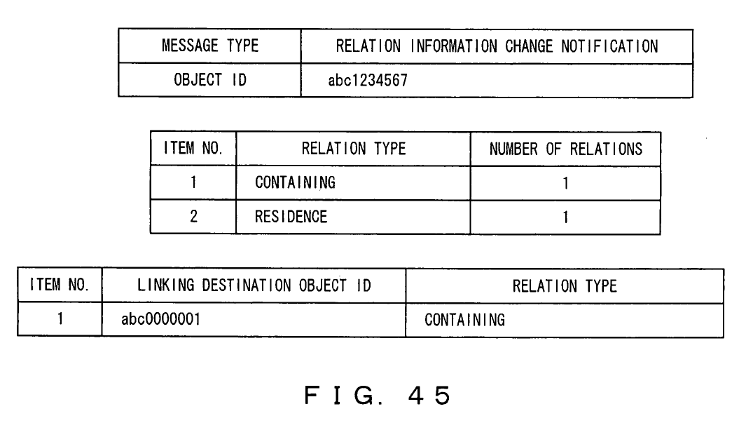

FIG. 45 shows an example of an example of a relation information change notification corresponding to the change notification condition set by the setting request shown in FIG. 38. In FIG. 38 a notification is to be issued as a condition when any of the relation type, number of relations, and linking destination object ID is changed. Meanwhile, a change notification shown in FIG. 45 indicates the contents of a notification issued when an object having an ID of abc1234567 is a linking source and an object having an ID of abc0000001 is a linking destination, and a relation “containing” is added as a relation type. The relation information whose relation type is “resident” is resident before the addition is made.

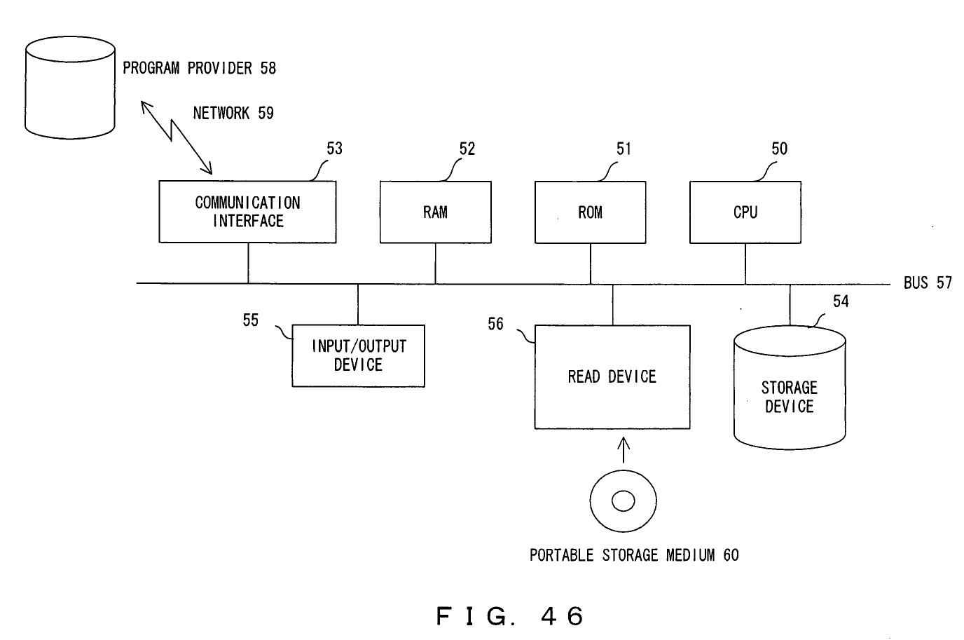

As described above, the details of the object relation information management program, etc. is explained. The program can be executed by a common computer system. FIG. 46 shows such a computer system, that is, the configuration of a hardware environment.

In FIG. 46, the computer system is configured by a central processing unit (CPU) 50, read only memory (ROM) 51, random access memory (RAM) 52, a communication interface 53, a storage device 54, an input/output device 55, a read device 56 of a portable storage medium, and a bus 57 for connecting all these components.

As the storage device 54, various storage devices such as a hard disk, a magnetic disk, etc. can be used, and these storage devices 54 or ROM 51 store the programs in the above-mentioned sequences and flowcharts, the programs in the claims for the patent of the present invention. By executing the programs by the CPU 50, the object relation information according to the embodiments of the present invention can be centrally managed, the amount of information can be reduced, and the relation information can be freely used by service users.

The above-mentioned programs can be stored in, for example, the storage device 54 from a program provider 58 through a network 59 and the communication interface 53, or can be stored in a portable storage medium 60 marketed and distributed, and set in the read device 56 for execution by the CPU 50. As the portable storage medium 60, various storage media such as a CD-ROM, a flexible disk, an optical disk, a magneto-optical disk, a DVD, etc. can be used. By reading the program stored in the storage media by the read device 56, the relation information can be managed in the format independent of the service according to the embodiments of the present invention.

As described above in detail, according to the present invention, by representing relation typein a describable format and representing relation direction by a linking destination object and a linking source object, and further, by enabling to add relation types according to the relation information easily, the object relation information can be not only used for a specific service use, but also a generally used relation information management system can be realized, thereby reducing the entire amount of information and improving the efficiency of the information process on various services.

When the relation information is referred to, the relation type can be included in the retrieval condition, and the condition under which the relation information change notification is issued can be specified by a key object, relation type, the number of relations, etc. Furthermore, by generating a cache of a relation information change log for the condition, the reduction of the retrieval speed can be prevented, and the device which receives a relation information change notification can shorten the time required to start the process corresponding to a change in relation information.

What is claimed is:

1. A computer-readable storage medium storing an object relation information management program used to direct a computer which manages relations between objects to perform the processes of:
receiving a registration request for relation information between objects from a user terminal; and
storing object relation information containing a type of relations between objects and a relation direction represented by a linking source and a linking destination in a storage device in response to the registration request.

2. The storage medium according to claim 1, wherein the object relation information management program further comprises the processes of:
receiving a deletion/change request for relation information between objects from a user terminal;
deleting or changing object relation information stored in the storage device in response to the deletion/change request; and
recording a registration/deletion/change result of the relation information as a change log.

3. The storage medium according to claim 2, wherein the object relation information management program further comprises the processes of:
managing a condition to be externally received and to be a notification condition under which a external notification is to be issued when contents of the change log satisfy the condition, and performing a notification execution process of externally issuing a notification when object relation information satisfying the notification condition is registered, deleted, or changed.

4. The storage medium according to claim 3, wherein the object relation information management program further comprises the processes of:
when the notification condition is externally received, generating a log cache having an area storing the contents of the change log in cache memory corresponding to the notification condition;
reflecting a registration/deletion/change result of the object relation information by contents of the log cache; and
the notification execution process determining whether or not the notification condition is satisfied by the contents of the log cache.

5. The storage medium according to claim 4, wherein the notification execution process filters the notification condition based on a relation type and a number of relations using the contents of the log cache for a specified object, and externally issues a notification based on a notification condition as a filtering result.

6. The storage medium according to claim 1, wherein the object relation information management program further comprises the processes of:
externally receiving a retrieval request for relation information about a specified object;
filtering the relation information about the specified object based on the relation type and a relation direction in response to the retrieval request, and externally outputting a filtering result as a retrieval result.

7. An object relation information managing method for managing a relation between objects, comprising:
receiving a registration request for relation information between objects from a user terminal; and
storing object relation information containing a type of relations between objects and a relation direction represented by a linking source and a linking destination in a storage device in response to the registration request.

8. The method according to claim 7, further comprising:
receiving a deletion/change request for relation information between objects from a user terminal;
deleting or changing object relation information stored in the storage device in response to the deletion/change request; and
recording a registration/deletion/change result of the relation information as a change log.

9. The method according to claim 8, further comprising:
managing a condition to be externally received and to be a notification condition under which a external notification is to be issued when contents of the change log satisfy the condition, and externally issuing a notification when object relation information satisfying the notification condition is registered, deleted, or changed.

10. The method according to claim 9, further comprising:
when the notification condition is externally received, generating a log cache having an area storing the contents of the change log in cache memory corresponding to the notification condition;
reflecting a registration/deletion/change result of the object relation information by contents of the log cache; and
during executing notification, determining whether or not the notification condition is satisfied by the contents of the log cache.

11. An object relation information management apparatus for managing a relation between objects, comprising:
a communication management device receiving a registration request for relation information between objects from a user terminal; and
an object relation information management device storing object relation information containing a type of relations between objects and a relation direction represented by a linking source and a linking destination in a storage device in response to the registration request.

12. The apparatus according to claim 11, further comprising
a change log management device, wherein:
the communication management device receives a deletion/change request for relation information between objects from a user terminal;
the object relation information management device deletes or changes object relation information stored in the storage device in response to the deletion/change request; and
the change log management device records a registration/deletion/change result of the relation information as a change log.

13. The apparatus according to claim 12, further comprising
a notification condition management device managing a condition to be externally received and to be a notification condition under which a external notification is to be issued when contents of the change log satisfy the condition, and externally issuing a notification when object relation information satisfying the notification condition is registered, deleted, or changed.

14. The apparatus according to claim 13, wherein:
when the notification condition is externally received, the change log management device generates a log cache having an area storing the contents of the change log in cache memory corresponding to the notification condition; reflects a registration/deletion/change result of the object relation information by contents of the log cache; and
the notification condition management device determines whether or not the notification condition is satisfied by the contents of the log cache.

15. An object relation information management apparatus for managing a relation between objects, comprising:
communication management means for receiving a registration request for relation information between objects from a user terminal; and
object relation information management means for storing object relation information containing a type of relations between objects and a relation direction represented by a linking source and a linking destination in a storage device in response to the registration request.
